(19) United States
(12) Patent Application Publication
(10) Pub. No.: US 2026/0347262 A1
(43) Pub. Date: Nov. 5, 2026

(54) CERAMIC MATERIAL, POWDER AND LAYER SYSTEM

(71) Applicant: Siemens Energy Global GmbH & Co. KG, Munich (DE)

(72) Inventor: Arturo Flores Renteria, Berlin (DE)

(73) Assignee: Siemens Energy Global GmbH & Co. KG, Munich (DE)

(21) Appl. No.: 19/731,081

(22) Filed: Jul. 5, 2026

Related U.S. Application Data
(63) Continuation of application No. 18/277,072, filed on Jan. 13, 2022, now Pat. No. 12,703,665.

(30) Foreign Application Priority Data
Feb. 18, 2021 (DE) 102021201565.4

(51) Int. Cl. C04B 35/486; C23C 28/04

(52) U.S. Cl. CPC C04B 35/486; C23C 28/042; C04B 2235/3217; C04B 2235/3225; C04B 2235/3244

(57) ABSTRACT

An improved ceramic material for heat insulation is achieved by the following selection of specific stabilizers and the adapted proportions: Base of zirconium dioxide (ZrO₂) with: 1.0 wt. % to 9.0 wt. % of base stabilizers: yttrium oxide (Y₂O₃), hafnium oxide (HfO₂), wherein at least yttrium oxide (Y₂O₃) is used, and at least one of the additional stabilizers: erbium oxide (Er₂O₃) and/or ytterbium oxide (Yb₂O₃) with a proportion of 0.2 wt. % to 20 wt. %.

### CROSS-REFERENCE TO RELATED APPLICATIONS

This application is a continuation of US Ser. No. 18/277,072 filed 13 Aug. 2023, which is a US National Stage of International Application No. PCT/EP2022/050634 filed 13 Jan. 2022, and claims the benefit thereof, which is incorporated by reference herein in its entirety. The International Application claims the benefit of German Application No. DE 10 2021 201 565.4 filed 18 Feb. 2021.

### TECHNICAL FIELD

The invention relates to a ceramic material and to a powder which can be used for ceramic layer systems.

### BACKGROUND OF THE INVENTION

Ceramics in general have a high thermal stability and are therefore often used as ceramic coatings on high-temperature components, such as for turbines, particularly for gas turbines.

The constant aim is to improve the heat insulation properties of the ceramic material.

### SUMMARY OF THE INVENTION

It is therefore an object of the invention to achieve the object stated above.

The object is achieved by a ceramic material as claimed, a ceramic powder as claimed, and a layer system as claimed.

Ceramic layers based on zirconium oxide with stabilizers are known; here, stabilized or fully stabilized zirconium oxide is often used, owing to its better thermal stability.

The goal of the concept, however, is to use partially stabilized zirconium oxide having an improved stability, particularly thermal stability, specifically a ceramic material based on zirconium oxide (ZrO₂), comprising:
1.0 wt % to 8.0 wt % of base stabilizers:
particularly with 2.0 wt % to 8.0 wt % of base stabilizers:
yttrium oxide (Y₂O₃), and/or hafnium oxide (HfO₂),
wherein at least yttrium oxide (Y₂O₃) is used,
and also
at least one of the additional stabilizers:
erbium oxide (Er₂O₃) and/or ytterbium oxide (Yb₂O₃)
with a fraction of 0.2 wt % to 20.0 wt %,
particularly with 1.0 wt % to 10.0 wt %,
very particularly with 2.0 wt % to 9.0 wt %,
and also in each case optionally
aluminum oxide (Al₂O₃) 0.1%-2.0%,
and allowed impurity levels (in each case max.):
calcium oxide (CaO) 0.1%-0.2%,
iron oxide (Fe₂O₃) 0.1%-0.2%,
magnesium oxide (MgO) 0.1%-0.2%,
silicon oxide (SiO₂) 0.1%-0.3%,
titanium oxide (TiO₂) 0.1%-0.2%.

Preferably, yttrium oxide (Y₂O₃) and hafnium oxide (HfO₂) are used as base stabilizers. It is also possible for only yttrium oxide (Y₂O₃) to be used as base stabilizer.

The ceramic material comprises preferably 2.5 wt % to 5.5 wt % of yttrium oxide (Y₂O₃), particularly 3.0 wt % to 5.0 wt % of yttrium oxide (Y₂O₃), very particularly 3.5 wt % to 4.0 wt % of yttrium oxide (Y₂O₃), to achieve good phase stability.

The ceramic material also comprises preferably hafnium oxide (HfO₂) >2.0 wt % to 4.0 wt %, particularly 2.2 wt % to 4.0 wt % of hafnium oxide (HfO₂), very particularly 2.4 wt % to 3.0 wt % of hafnium oxide (HfO₂).

Also advantageous is a ceramic material wherein the hafnium oxide (HfO₂) content is 0.2 wt % to <2.0 wt %, particularly 0.2 wt % to 1.8 wt % of hafnium oxide (HfO₂), very particularly 0.2 wt % to 1.6 wt % of hafnium oxide (HfO₂).

Secondary particles such as aluminum oxide (Al₂O₃) may be present with a fraction of 0.2 wt % to 1.5 wt % of aluminum oxide (Al₂O₃), particularly of 0.2 wt % to 1.2 wt %.

The fraction of aluminum oxide (Al₂O₃) may also be 1.5 wt % to 3.0 wt % of aluminum oxide (Al₂O₃) as well, particularly >2.0 wt % to 2.5 wt % of aluminum oxide (Al₂O₃).

As additional stabilizers, preferably only ytterbium oxide (Yb₂O₃) is used.

Other advantageous variants are, as additional stabilizers, only erbium oxide (Er₂O₃), or that as additional stabilizers only ytterbium oxide (Yb₂O₃) and erbium oxide (Er₂O₃) are connected.

Advantageous compositions are therefore ZrO₂—HfO₂—Y₂O₃—Yb₂O₃ or else ZrO₂—HfO₂—Y₂O₃—Yb₂O₃—Al₂O₃.

The weights of the additional stabilizers are preferably 5.5 wt % to 8.5 wt % of ytterbium oxide (Yb₂O₃), particularly 6.0 wt % to 8.0 wt % of ytterbium oxide (Yb₂O₃), very particularly 6.5 wt % to 7.5 wt % of ytterbium oxide (Yb₂O₃), and, respectively, 2.0 wt % to 4.0 wt % of erbium oxide (Er₂O₃), particularly 2.5 wt % to 3.5 wt % of erbium oxide (Er₂O₃).

For the fractions among one another, the following is valid particularly:
(8.0−x) wt % of Y₂O₃+(2-4)x wt % of Yb₂O₃/Er₂O₃,
particularly (6.0−x) wt % of Y₂O₃+(2-4)x wt % of Yb₂O₃/Er₂O₃,
where x represents the weight fraction of the additional stabilizers.

A ceramic powder comprises, more particularly consists of, a composition of a material according to listings above, with or without binder.

One advantageous layer system comprises a metallic substrate, optionally a metallic adhesion promoter layer, and at least one ceramic layer on the basis of the ceramic material of the invention.

A metallic adhesion promoter layer between the ceramic layer and the metallic substrate, particularly on the basis of NiCoCrAlY, serves for advantageous adhesion.

A ceramic sublayer (not the TGO) below the ceramic layer composed of a ceramic material is at least 20% thinner in configuration and comprises preferably 8YSZ, i.e., zirconium oxide stabilized with 3 mol % to 4 mol % of yttrium.

Yttrium oxide is used in any case as stabilizer.

This ceramic material may be produced as powder, and so there may be further additions present as when using abrasive layers which comprise cubic boron nitride or other abrasive particles.

### BRIEF DESCRIPTION OF DRAWINGS

FIG. 1 shows an embodiment of a layer system,

FIG. 2 shows another embodiment of a layer system.

### DETAILED DESCRIPTION

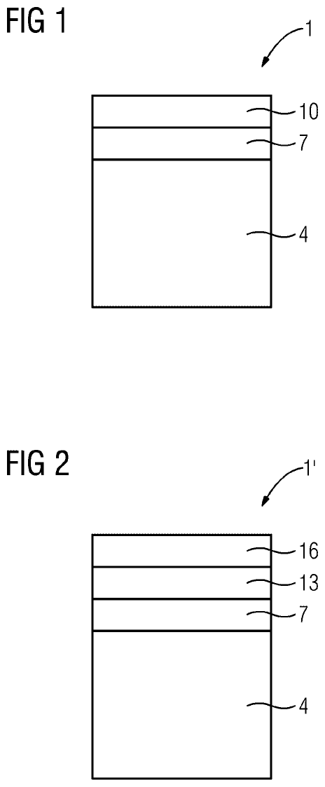

In a layer system (FIG. 1), a ceramic layer 10 is applied to metal, and, in the case of preferably-used nickel or cobalt-based superalloys, a metallic adhesion layer 7 is present in-between, forming aluminum oxide.

The metallic adhesion promoter layer is preferably an aluminide, platinum aluminide or, as a basis, represents an NiCoCrAl layer.

The ceramic layer composed of the ceramic material may be produced by means of EB-PVD, plasma spraying (APS, . . . ), and has a columnar structure or a DVC (dense vertical cracked) structure.

The layer 10 has a preferential layer thickness of 100 μm to 1000 μm.

As shown in FIG. 2, this ceramic layer 10 may also comprise a ceramic sublayer 13, which differs significantly from the ceramic layer 16, i.e. comprises no Yb₂O₃ and/or no Er₂O₃.

The layer thickness of the ceramic sublayer 13, however, is at least 20% thinner in configuration than that of the ceramic material of the invention in the ceramic layer 16.

The ceramic sublayer comprises 8YSZ, i.e., zirconium oxide stabilized with 3 mol % to 4 mol % of yttrium.

1. A ceramic material based on zirconium oxide (ZrO₂), comprising (in wt %):
1.0 wt % to 8.0 wt % of base stabilizers,
wherein yttrium oxide (Y₂O₃) is the only base stabilizer,
additional stabilizers comprising:
erbium oxide (Er₂O₃) and/or ytterbium oxide (Yb₂O₃)
with a fraction of 0.2 wt % to 20.0 wt %,
further comprising:
aluminum oxide (Al₂O₃) 0.1%-3.0 wt %
and further comprising allowed impurity levels:
calcium oxide (CaO) up to 0.2 wt %
iron oxide (Fe₂O₃) up to 0.2 wt %
magnesium oxide (MgO) up to 0.2 wt %
silicon oxide (SiO₂) up to 0.3 wt %
titanium oxide (TiO₂) up to 0.2 wt %.

2. The ceramic material as claimed in claim 1, comprising
2.5 wt % to 5.5 wt % of yttrium oxide (Y₂O₃).

3. The ceramic material as claimed in claim 1, which comprises as additional stabilizers only erbium oxide (Er₂O₃).

4. The ceramic material as claimed in claim 1, which comprises as additional stabilizers ytterbium oxide (Yb₂O₃) and erbium oxide (Er₂O₃).

5. The ceramic material as claimed in claim 1, comprising
5.5 wt % to 8.5 wt % of ytterbium oxide (Yb₂O₃).

6. The ceramic material as claimed in claim 1, comprising
2.0 wt % to 4.0 wt % of erbium oxide (Er₂O₃).

7. A ceramic material based on zirconium oxide (ZrO2), comprising (in wt %):
up to 8.0 wt % of base stabilizers, the base stabilizers comprising:
comprising hafnium oxide (HfO₂) >2.0 wt % to 4.0 wt % and yttrium oxide (Y₂O₃), additional stabilizers comprising:
erbium oxide (Er₂O₃) and/or ytterbium oxide (Yb₂O₃)
with a fraction of 0.2 wt % to 20.0 wt %,
further comprising:
aluminum oxide (Al₂O₃) 0.1%-3.0 wt %
and further comprising allowed impurity levels:
calcium oxide (CaO) up to 0.2 wt %
iron oxide (Fe₂O₃) up to 0.2 wt %
magnesium oxide (MgO) up to 0.2 wt %
silicon oxide (SiO₂) up to 0.3 wt %
titanium oxide (TiO₂) up to 0.2 wt %.

8. The ceramic material as claimed in claim 7, comprising
2.5 wt % to 5.5 wt % of yttrium oxide (Y₂O₃).

9. The ceramic material as claimed in claim 7, which comprises as additional stabilizers only erbium oxide (Er₂O₃).

10. The ceramic material as claimed in claim 7, which comprises as additional stabilizers ytterbium oxide (Yb₂O₃) and erbium oxide (Er₂O₃).

11. The ceramic material as claimed in claim 7, comprising
5.5 wt % to 8.5 wt % of ytterbium oxide (Yb₂O₃).

12. The ceramic material as claimed in claim 7, comprising
2.0 wt % to 4.0 wt % of erbium oxide (Er₂O₃).

13. A ceramic material based on zirconium oxide (ZrO2), comprising (in wt %):
1.0 wt % to 8.0 wt % of base stabilizers, the base stabilizers comprising:
yttrium oxide (Y₂O₃) and optionally hafnium oxide (HfO₂),
additional stabilizers comprising:
at least one of ytterbium oxide (Yb2O3) 5.5 wt % to 8.5 wt % and erbium oxide (Er₂O₃)
with a fraction of 0.2 wt % to 20.0 wt %,
further comprising:
aluminum oxide (Al₂O₃) 0.1%-3.0 wt %
and further comprising allowed impurity levels:
calcium oxide (CaO) up to 0.2 wt %
iron oxide (Fe₂O₃) up to 0.2 wt %
magnesium oxide (MgO) up to 0.2 wt %
silicon oxide (SiO₂) up to 0.3 wt %
titanium oxide (TiO₂) up to 0.2 wt %.

14. The ceramic material as claimed in claim 13, comprising only
yttrium oxide (Y₂O₃) as base stabilizer.

15. The ceramic material as claimed in claim 13, comprising
2.5 wt % to 5.5 wt % of yttrium oxide (Y₂O₃).

16. The ceramic material as claimed in claim 13,
wherein the hafnium oxide (HfO₂) content is >2.0 wt % to 4.0 wt %.

17. The ceramic material as claimed in claim 13, which comprises as additional stabilizers only erbium oxide (Er₂O₃).

18. The ceramic material as claimed in claim 13, which comprises as additional stabilizers ytterbium oxide (Yb₂O₃) and erbium oxide (Er₂O₃).

19. The ceramic material as claimed in claim 13, comprising
2.0 wt % to 4.0 wt % of erbium oxide (Er₂O₃).
